(19) United States
(12) Patent Application Publication
(10) Pub. No.: US 2013/0088843 A1
(43) Pub. Date: Apr. 11, 2013

(54) MOTHERBOARD ASSEMBLY HAVING SERIAL ADVANCED TECHNOLOGY ATTACHMENT DUAL IN-LINE MEMORY MODULE

(71) Applicants: WEI-DONG CONG, Shenzhen City (CN); GUO-YI CHEN, Shenzhen City (CN)

(72) Inventors: WEI-DONG CONG, Shenzhen City (CN); GUO-YI CHEN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/284,967

(22) Filed: Oct. 30, 2011

(30) Foreign Application Priority Data
Oct. 6, 2011 (CN) 201110292871.1

(51) Int. Cl. H05K 1/14

(52) U.S. Cl. 361/785

(57) ABSTRACT

A motherboard assembly includes a motherboard having an expansion slot and two storage device interfaces, and a serial advanced technology attachment dual in-line memory module (SATA DIMM) with a circuit board. A first extending board is formed on a top side of the circuit board. An edge connector is arranged on the first extending board and connected to the second storage device interface and a universal serial bus (USB) control chip. A second extending board is extended from an end edge of the circuit board and includes a connector connected to the first storage device interface. A bottom side of the second extending board is in alignment with a bottom side of the circuit board. A second edge connector is arranged on the bottom edges of the second extending board and the circuit board.

### CROSS-REFERENCE OF RELATED ART

Relevant subject matter is disclosed in a pending U.S. patent application with application Ser. No. 13/228,459 filed on Sep. 9, 2011, with the same title “MOTHERBOARD ASSEMBLY HAVING SERIAL ADVANCED TECHNOLOGY ATTACHMENT DUAL IN-LINE MEMORY MODULE”, which is assigned to the same assignee as this patent application.

### BACKGROUND

1. Technical Field

The present disclosure relates to a motherboard assembly having a serial advanced technology attachment dual in-line memory module (SATA DIMM).

2. Description of Related Art

Solid state drives (SSD) store data on chips instead of on magnetic or optical discs. One type of SSD has the form factor of a DIMM module and it is called a SATA DIMM module. The SATA DIMM module can be inserted into a memory slot of a motherboard, to receive voltages from the motherboard through the memory slot and receive hard disk drive (HDD) signals through SATA connectors arranged on the SATA DIMM module and connected to a SATA connector of the motherboard. However, the number of the SATA connectors arranged on the motherboard are limited, thus, it will bring some difficult that the motherboard cannot connect some SATA DIMM modules for expansion a storage capacity of the motherboard. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawing, like reference numerals designate corresponding parts throughout the several views.

FIG. 1 is an exploded, isometric view of a motherboard assembly in accordance with an exemplary embodiment of the present disclosure.

FIGS. 2 and 3 are assembled, isometric views of the motherboard assembly of FIG. 1.

### DETAILED DESCRIPTION

The disclosure, including the drawings, is illustrated by way of example and not by way of limitation. References to “an” or “one” embodiment in this disclosure are not necessarily to the same embodiment, and such references mean at least one.

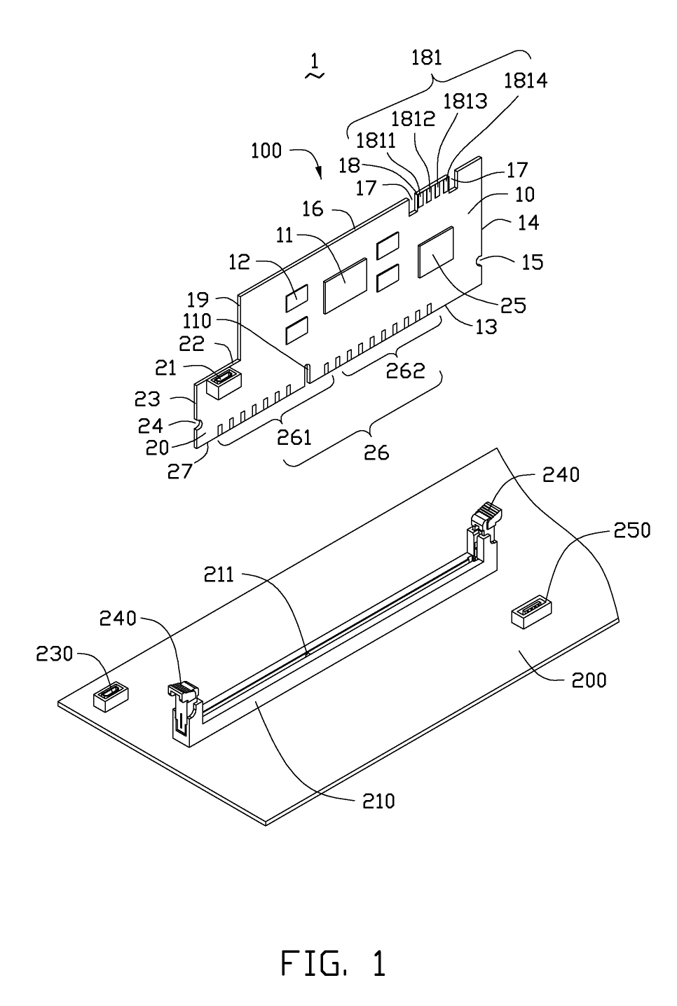

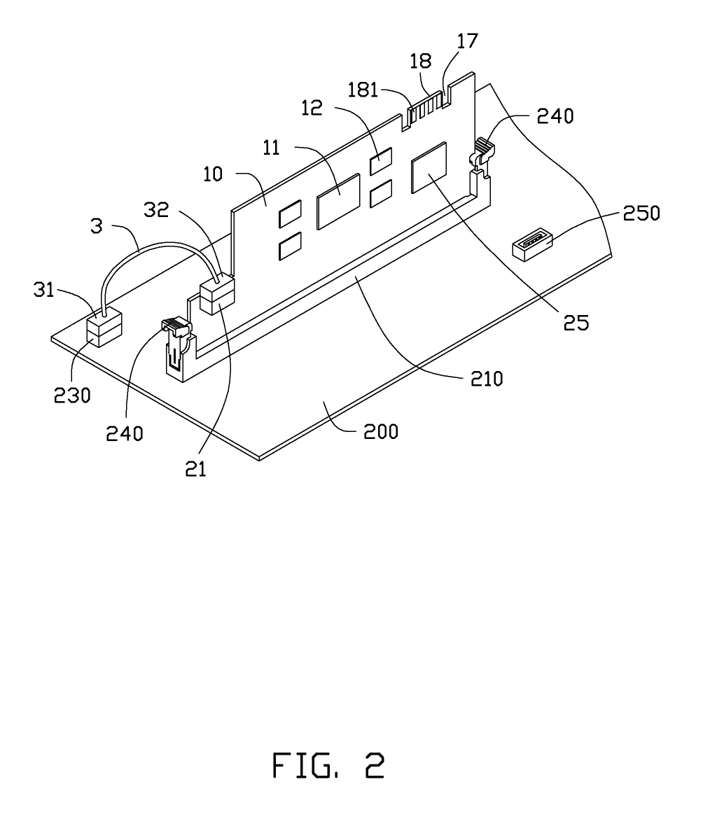

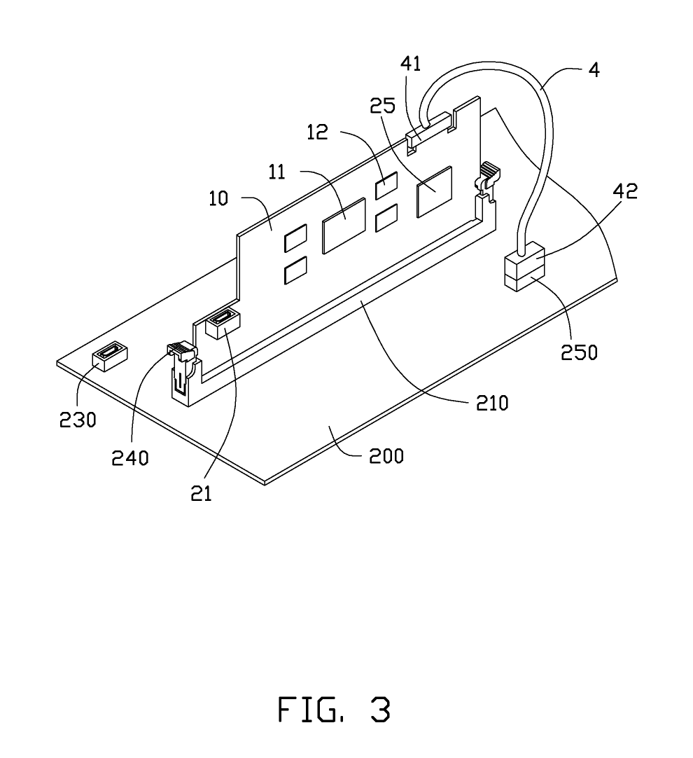

Referring to FIGS. 1 to 3, a motherboard assembly 1 in accordance with an exemplary embodiment includes a serial advanced technology attachment dual in-line memory module (SATA DIMM) 100 and a motherboard 200. An expansion slot 210, and two storage device interfaces 230 and 250 are arranged on the motherboard 200. The expansion slot 210 includes a protrusion 211 arranged in the expansion slot 210, and two fixing elements 240 set on two ends of the expansion slot 210 respectively. In one embodiment, the expansion slot 210 is a double data rate type three (DDR3) memory slot. The storage device interface 230 is a SATA connector. The storage device interface 250 is a universal serial bus (USB) connector.

The SATA DIMM module 100 includes a substantially rectangular circuit board 10. A SATA control chip 11, a USB control chip 25, and a plurality of storage chips 12 connected to the SATA control chip 11 and the USB control chip 25 are arranged on the circuit board 10. A notch 110 is defined in a bottom edge 13 of the circuit board 10. A groove 15 is defined in an end edge 14 of the circuit board 10. Two voids 17 are defined in a top edge 16 of the circuit board 10. A first extending board 18 is formed on the top edge 16, coplanar with the circuit board 10 and located between the voids 17. An edge connector 181 is arranged on the first extending board 18, and includes a signal input pin 1811, a signal output pin 1812, a power pin 1813, and a ground pin 1814. The power pin 1813, the signal input pin 1811, and the signal output pin 1812 are connected to the USB control chip 25. The ground pin 1814 is connected to a ground layer (not shown) of the circuit board 10. The edge connector 181 is connected to the storage device interface 250 by a cable 4 with two interfaces 41 and 42. In one embodiment, the edge connector 181 accords with a USB standard.

A second extending board 20 is extended from an end edge 19 of the circuit board 10 opposite to the groove 15, and is coplanar with the circuit board 10. A connector 21, such as a SATA connector, is arranged on the second extending board 20 and located adjacent to a top side 22 of the second extending board 20. The connector 21 is connected to the storage device interface 230 through a cable 3 with two storage device interfaces 31 and 32. A bottom edge 27 of the second extending board 20 is in alignment with and connected to the bottom edge 13. An edge connector 26 is arranged on the bottom edges 27 and 13, to be inserted into the expansion slot 210, and includes a plurality of power pins 261 and a plurality of ground pins 262. The power pins 261 are connected to the SATA control chip 11, the USB control chip 25, and the storage chips 12. The ground pins 262 are connected to the ground layer of the circuit board 10. A groove 24 is defined in an end edge 23 of the second extending board 20 opposite to the circuit board 10. The top side 22 of the second extending board 20 is lower than the top edge 16 of the circuit board 10. When the connector 21 is connected to a storage device interface, a top surface of the storage device interface is lower than or coplanar with the top edge 16. Interference is thus reduced between the SATA DIMM module 100 and a chassis (not shown) when the SATA DIMM module 100 is mounted on the motherboard 200 accommodated in the chassis. In other embodiments, the first extending board 18 may be formed on the end edge 14 or 19, or formed on the end edge 23.

In assembly, the edge connector 26 is inserted into the expansion slot 210, and the protrusion 211 engages in the notch 110. The fixing elements 240 engage in the grooves 15 and 24, to fix the SATA DIMM module 100 to the expansion slot 210. If the SATA DIMM module 100 controls the storage chips 12 to store data by receiving a SATA signal, the connector 21 is connected to the storage device interface 230 by the cable 3. If the SATA DIMM module 100 controls the storage chips 12 to store data by receiving a USB signal, the edge connector 181 is connected to the storage device interface 250 by the cable 4.

In use, when the connector 21 is connected to the storage device interface 230 by the cable 3 and the motherboard 200 receives power, the motherboard 200 outputs a voltage to the SATA DIMM module 100 through the expansion slot 210 and the edge connector 26. At the same time, the motherboard 200 outputs a control signal, such as a hard disk drive (HDD) signal, to the SATA control chip 11 through the storage device interface 230, the cable 3, and the connector 21, to enable communication between the SATA DIMM module 100 and the motherboard 200.

When the edge connector 181 is connected to the storage device interface 250 by the cable 4 and the motherboard 200 receives power, the motherboard 200 outputs a voltage to the SATA DIMM module 100 through the expansion slot 210 and the edge connector 26. At the same time, the motherboard 200 outputs a control signal, such as a USB signal, to the USB control chip 25 through the storage device interface 250, the cable 4, and the edge connector 181, to enable communication between the SATA DIMM module 100 and the motherboard 200.

The SATA DIMM module 100 can be inserted into the expansion slot 210 through the edge connector 26, to receive voltage and fix the SATA DIMM module 100 on the motherboard 200. The SATA DIMM module 100 either receives a SATA control signal from the motherboard 200 through the connector 21 or receives a USB control signal from the motherboard 200 through the edge connector 181, to enable communication between the SATA DIMM module 100 and the motherboard 200. Therefore, the SATA DIMM module 100 can be used even if the number of the SATA connectors arranged on the motherboard 200 is limited.

Even though numerous characteristics and advantages of the disclosure have been set forth in the foregoing description, together with details of the structure and function of the disclosure, the disclosure is illustrative only, and changes may be made in detail, especially in matters of shape, size, and the arrangement of parts within the principles of the disclosure to the full extent indicated by the broad general meaning of the terms in which the appended claims are expressed.

What is claimed is:

1. A motherboard assembly comprising:
a motherboard comprising:
an expansion slot arranged on the motherboard; and
a first storage device interface arranged on the motherboard;
a second storage device interface arranged on the motherboard; and
a serial advanced technology attachment dual in-line memory module (SATADIMM) comprising:
a circuit board;
a SATA control chip arranged on the circuit board;
a universal serial bus (USB) control chip arranged on the circuit board;
a plurality of storage chips arranged on the circuit board and connected to the SATA control chip and the USB control chip;
a part of a top edge of the circuit board forms a first extending board, wherein a first edge connector is arranged on the first extending board, and comprises a signal input pin, a signal output pin, a first power pin, and a first ground pin, wherein the signal input pin, the signal output pin, and the first power pin are connected to the USB control chip, the first edge connector is connected to the second storage device interface of the motherboard; and
a second extending board extended from an end edge of the circuit board and coplanar with the circuit board, wherein a connector is arranged on the second extending board, a bottom edge of the second extending board is in alignment with a bottom edge of the circuit board, a second edge connector is arranged on the bottom edges of the second extending board and the circuit board, to be inserted into the expansion slot of the motherboard, the second edge connector comprises a plurality of second power pins and a plurality of second ground pins, the second power pins are connected to the SATA control chip, the USB control chip, and the storage chips, the connector of the second extending board is connected to the first storage device interface of the motherboard.

2. The motherboard assembly of claim 1, wherein the first storage device interface is a SATA connector, the second storage device interface is a USB connector.

3. The motherboard assembly of claim 1, wherein the first edge connector accords with USB standard, the connector of the second extending board is a SATA connector.

4. The motherboard assembly of claim 1, wherein a notch is defined in the bottom edge of the circuit board, the expansion slot comprises a protrusion to engage in the notch of the circuit board when the SATA DIMM module is inserted into the expansion slot.

5. The motherboard assembly of claim 1, wherein the connector of the second extending board is connected to a first interface at a first end of a cable, a second interface at a second end of the cable is connected to the first storage device interface of the motherboard.

6. The motherboard assembly of claim 1, wherein the first edge connector is connected to the second storage device interface of the motherboard through a cable with two interfaces.

7. The motherboard assembly of claim 1, wherein the circuit board is rectangular, two grooves are respectively defined in an end edge of the circuit board opposite to the second extending board and an end edge of the second extending board opposite to the circuit board, the expansion slot further comprises two fixing elements formed at two ends of the expansion slot, to engage in the grooves.

8. The motherboard assembly of claim 7, wherein the expansion slot is a double data rate type three memory slot.

9. The motherboard assembly of claim 1, wherein two voids are defined in the top edge of the circuit board, the first extending board is formed between the voids, and coplanar with the circuit board.
